(19) United States
(12) Patent Application Publication
(10) Pub. No.: US 2026/0123409 A1
(43) Pub. Date: Apr. 30, 2026

(54) Component Carrier With Protruding Thermal Structure and Manufacture Method

(71) Applicant: AT&S Austria Technologie & Systemtechnik Aktiengesellschaft, Leoben (AT)

(72) Inventor: Jeesoo MOK, Leoben (AT)

(21) Appl. No.: 19/115,770

(22) PCT Filed: Oct. 5, 2023
(86) PCT No.: PCT/EP2023/077638

§ 371 Date: Mar. 26, 2025

(30) Foreign Application Priority Data
Oct. 12, 2022 (CN) 202211247601.3

(51) Int. Cl. H10W 40/22; H10W 40/00; H10W 70/05; H10W 70/685

(52) U.S. Cl. CPC H10W 40/22; H10W 40/03; H10W 70/05; H10W 70/685

(57) ABSTRACT

A component carrier includes i) a stack with at least one electrically conductive layer structure and/or at least one electrically insulating layer structure, ii) an electronic component embedded in the stack; and iii) a thermal structure, configured to dissipate thermal energy produced by the electronic component towards and beyond a main surface of the stack. The thermal structure includes iiia) a base structure mounted on and/or at least partially embedded in the stack, in particular flush with one of the layer structures of the stack, and iiib) a plurality of protrusions, protruding from the base structure, and extending beyond the main surface of the stack.

### CROSS REFERENCE TO RELATED APPLICATIONS

This application is the U.S. national phase of International Application No. PCT/EP2023/077638 filed on Oct. 5, 2023, which designated the U.S. and claims priority to Patent Application No. 202211247601.3, filed on Oct. 12, 2022, with the China National Intellectual Property Administration, the entire contents of each of which are hereby incorporated herein by reference.

### TECHNICAL FIELD

The disclosure relates to a component carrier with a stack, an electronic component, and a thermal structure that comprises a plurality of protrusions. Further, the disclosure relates to a method of manufacturing the component carrier. Additionally, the disclosure relates to a semi-finished product, i.e. the component carrier under manufacture.

Thus, the disclosure may relate to the technical field of component carriers such as printed circuit boards and IC substrates, in particular in the context of heat dissipation.

### TECHNOLOGICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. At the same time, component carriers shall be mechanically robust and electrically and magnetically reliable so as to be operable even under harsh conditions.

In particular, dissipating heat from heat-producing electronic components (e.g. embedded chips) may be considered a challenge, especially in the field of coreless component carriers such as fan-out wafer level packages (FOWLP).

### SUMMARY

There may be a need to enhance the heat dissipation capacity of a component carrier.

A component carrier, a manufacture method, and a semi-finished product are provided.

According to a first embodiment of the disclosure, it is described a component carrier (in particular a coreless component carrier), wherein the component carrier comprises: i) a stack comprising at least one electrically conductive layer structure and/or at least one electrically insulating layer structure, ii) an (electronic) component (e.g. an IC) embedded in the stack; and iii) a thermal structure, configured to dissipate thermal energy produced by the electronic component towards and beyond a main surface (being parallel to the directions of main extension (along x-and y-axis) of the component carrier) of the stack, wherein the thermal structure comprises: iiia) a base structure mounted on and/or at least partially embedded in the stack (in particular flush with one of the layer structures of the stack), and iiib) a plurality of protrusions, protruding from the base structure (in particular connected to the base structure, more in particular monolithically formed), and (at least partially) extending beyond the main surface of the stack.

According to a second embodiment of the disclosure, it is described a method for manufacturing a component carrier, the method comprising: i) forming a stack comprising at least one electrically conductive layer structure and/or at least one electrically insulating layer structure; ii) embedding an electronic component in the stack; and iii) forming a thermal structure, so that the thermal structure dissipates thermal energy produced by the electronic component towards (and beyond) a main surface of the stack. The thermal layer structure comprises a base structure mounted on and/or at least partially embedded in the stack, in particular flush with one of the layer structures of the stack, and a plurality of protrusions, protruding from the base structure, and (at least partially) extending beyond the main surface of the stack.

According to a third embodiment of the disclosure, it is described a semi-finished product, comprising: i) a high temperature resistant layer, in particular a dry film resist, in particular wherein the high temperature resistant layer comprises recesses filled with a plurality of protrusions; and ii) a photo-imageable dielectric, PID, layer structure on top of the high temperature resistant layer, in particular wherein the PID layer structure comprises a base structure cavity filled with a base structure, more in particular wherein the thickness of the manufacture stack is 300 μm or less.

### OVERVIEW OF EMBODIMENTS

In the context of the present document, the term “thermal structure” may particularly denote any structure suitable to dissipate heat in the context of a component carrier. In a basic example, a thermal structure may be a metal plate or metal block, since metal efficiently guides heat (in comparison to insulating component carrier materials such as resins). Alternatively, a thermal structure can be a plate or block done in electrical insulating material but having good thermal conductive properties. In a more advanced example, a thermal structure may comprise so-called fins that distribute heat away from the component carrier. This may be done especially efficiently due to a large surface area of the fins/protrusions. In a preferred example, a thermal structure comprises a base (layer) structure and a protruding portion, wherein the base structure is configured to function as a support of the protruding portion.

In the context of the present document, the term “protruding portion” may particularly denote a structure mounted on or connected to a base structure that extends away from the base structure. For example, a plurality of column-shaped (e.g. rectangular or circular) structures may be connected to the base structure. According to one embodiment, said structure may comprise the above-mentioned fins.

In a further embodiment, the protruding portions can (at least partly) have a pattern distribution or different distributions, such as a peripheral distribution (with respect to the thermal structure and/or the component carrier), a random distribution, etc.

In an example, the base structure may be mounted on a component carrier main surface (in particular partially embedded in the component carrier), while the protruding portions extend away from the component carrier, thereby dissipating heat beyond the main surface.

In the context of the present document, the term “electronic component” may in particular refer to any component that may be embedded in a component carrier and is electrically connected/connectable to an electrically conductive layer structure of the component carrier. The electronic component may hence be an active component (e.g. an IC) or a passive component (e.g. a capacitor).

In the context of the present document, the term “component carrier” may particularly denote any support structure which can accommodate one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In an embodiment, the component carrier comprises a (layer) stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

According to an example embodiment, the disclosure may be based on the idea that the heat dissipation capacity of a component carrier can be enhanced, when a thermal structure is applied at a main surface of the component carrier and above a heat producing component, wherein the thermal structure comprises a plurality of protruding portions that transport the heat from the component beyond the main surface of the component carrier.

Conventionally, heat dissipation structures guide the heat produced by an electronic component along the component carrier layer stack in a horizontal direction (e.g. by a heat pipe). Alternatively, metal vias or metal blocks may dissipate heat in the vertical direction through the stack. Since the heat passes through a large part of the component carrier, the conventional heat paths may not be very efficient.

However, according to the disclosure, the heat may be directly transferred from the heat producing component through the base structure (on top of the component), and the plurality of protrusions, away from the component carrier main surface. Such a heat path may be especially efficient, especially in case of coreless applications. Regarding the manufacture, the thermal structure may serve as a surprisingly efficient and robust basis for further layer build-up and may thus be used as the supporting substrate during component carrier manufacturing.

According to an embodiment, the component carrier further comprises a redistribution layer structure, at least partially embedded in the stack and configured to electrically connect the embedded electronic component to a further main surface of the stack. This may provide the advantage that small electric component pads may be securely connected to larger pads at the further main surface. Accordingly, robust and reliable electric connection of the component may be enabled. The component carrier may hereby serve as an interposer.

According to a further embodiment, the further main surface is opposed to the main surface. This may provide the direction of the exchanged heat path away from the redistribution structure, the latter being preferably connected to an additional component and/or an additional component carrier (i.e. a PCB) the functionality of that can be affected by the exchanged heat.

According to a further embodiment, the component carrier is configured as a coreless component carrier. In general, a component carrier comprises a (central) core layer structure that provides stability and robustness. Often, the core is formed by a fully cured insulating material such as FR4, i.e. no prepreg (not fully cured). A coreless component carrier may provide the advantage that it is thinner and can be applied in a more flexible manner.

According to a further embodiment, the component carrier is configured as a fan-out wafer-level-package or a fan-out panel-level-package.

According to a further embodiment, the component carrier is configured as a high-density package for (moderate) heat production.

According to a further embodiment, the thermal structure is configured as an integral part of the stack. This may provide the advantage that stack and thermal structure are connected in a robust and stable manner. For example, the base structure may be part of one or more layer structures of the stack. In a specific example, the base structure is surrounded by a solder mask layer structure. In another example, the base structure may be surrounded by one or more other layer structures of the stack. In an example, only the base structure and not the protrusion portion is integrated with the stack.

According to a further embodiment, the base structure is (one of) the outermost layer(s) of the stack/component carrier. This may provide the advantage that the heat produced by the electronic component may be directly guided away from the main surface (minimal distance) instead of being transported through the stack. In the case that the base structure is surface mounted, it may be the outermost layer. But also, when surrounded by another layer, the base structure may still be (part of) the outermost layer of the stack.

According to a further embodiment, the thermal structure further comprises a coating layer, in particular a surface finish, that covers the plurality of protrusions. This may provide the advantage that the protrusions are efficiently protected against oxidation without hindering the dissipation of heat. In particular, the coating layer may comprise a material that efficiently dissipates heat, comparable to the protrusion material. Examples of suitable surface finish materials are provided further below.

According to a further embodiment, the plurality of protrusions comprises a height in the range 100 μm to 200 μm. This range may be an optimal compromise between a low height of the component carrier and an efficient heat dissipation.

According to a further embodiment, the plurality of protrusions comprises essentially vertical sidewalls, in particular thereby reflecting a manufacture step of photolithography. As will be described below, the photolithography methodology may be applied when manufacturing the protrusions. It may be inherent to photolithographic methods to form vertically (essentially) straight sidewalls in comparison to etching or laser-drilling. Hence, the essentially vertical sidewalls may be a structural feature that directly reflects the manufacturing process.

According to a further embodiment, the protrusions of the plurality of protrusions comprise the same shapes or different shapes. Depending on the desired application, similar or different shapes may be preferred.

According to a further embodiment, the base structure comprises a larger width than the electronic component. Thereby, an especially efficient heat dissipation may be enabled.

According to a further embodiment, the electronic component is embedded in a cavity, in particular encapsulated in the cavity, and wherein the base structure comprises a larger width than the cavity. This design may also allow for an especially efficient heat dissipation (thermal path). Further, the thermal structure may be applied as a support structure to build-up the layer stack. In this embodiment, a base structure with a larger width (than the component/cavity) may be a robust support for embedding (and encapsulating) the electronic component in the cavity.

According to a further embodiment, a thermal path (T) is established directly from the electronic component to the thermal structure without an electrically insulating material in between or the thermal path (T) is established from the electronic component to the thermal structure with at least one layer structure in between, in particular an adhesive layer.

A direct connection may enable and especially reliable heat flow without any interruption. The adhesive layer in turn may be advantageous when placing the component in the cavity. Hereby, the adhesive layer may be very thin, so that it may have only a negligible effect on the heat dissipation.

According to a further embodiment, the component carrier further comprises a vertical electric connection embedded in the stack, in particular wherein the vertical electric connection extends through the stack, wherein an upper part of the vertical electric connection is electrically connectable at the main surface of the stack. Such a through connection may enable a variety of approaches, depending on the indented functionality. The vertical electric connection may comprise a plurality of electrically conductive layer structures (traces) and electrically conductive vias (e.g. filled with copper).

According to a further embodiment, the component carrier further comprises a metal structure arranged besides the thermal structure, wherein the metal structure extends at least partially beyond the main surface, in particular wherein the metal structure forms the outermost portion of the vertical electric connection. This structural feature may directly reflect a manufacture step of forming the metal structure (and the outermost portion of the vertical electric connection) together with the thermal structure, e.g. by a photolithographic process.

According to a further embodiment, the metal structure comprises a larger width or a smaller width than the upper part (outermost part) of the vertical electric connection (see FIGS. 2 and 3 below). Depending on the desired application, either a robust support or a more reliable electric connection may be preferred.

According to a further embodiment, the metal structure comprises the same height as the plurality of protrusions.

According to a further embodiment, the upper part of the vertical electric connection is arranged at the same vertical height (z) as the base structure.

These structural features may directly reflect a manufacture step, in which the metal structure and the thermal structure are manufactured together, since both were formed in one and the same layer.

According to a further embodiment, the component carrier further comprises an adhesive layer, embedded in the stack and arranged (at least partially) below the thermal structure. Said adhesive layer may be arranged between the thermal structure and an electrically insulating layer structure of the stack. In a specific example, the adhesive layer comprises a DAF (die attaching film).

According to a further embodiment, the component carrier further comprises a protection layer embedded in the stack. The electronic component (and the encapsulation material) may be surrounded by the protection layer.

According to a further embodiment, the method further comprises forming the thermal structure on a temporary carrier, in particular a fabric-based (e.g. a non-woven and/or composite) temporary carrier, more in particular a Dyneema composite fabric (DCF) temporary carrier. DCF is a composite fabric with a non-woven, laminate material. DCF may be especially efficient for high strength and low weight applications. Accordingly, a DCF carrier may be advantageously applied for the manufacture method.

According to a further embodiment, the method further comprises i) providing a high temperature resistant dielectric layer, in particular a dry film resist/photoresist; ii) patterning the high temperature resistant dielectric layer to obtain a structured layer; and iii) forming the plurality of protrusions in recesses of the structured layer, in particular by plating.

In an example, a plurality of protrusions is formed on a temporary carrier (in particular the DCF carrier) in recesses of the high temperature resistant dielectric layer (preferably dry film). Hereby, even small structures (microstructures) with vertically straight sidewalls may be obtained. Patterning of the high temperature resistant dielectric layer may be done by photolithography, in particular when the high temperature resistant dielectric layer is a photoresist (polymer dry film).

A photoresist may in general protect metal paths which shall not be etched away, while metal areas which shall be etched away are not covered with the photoresist. First, for this purpose, an entire layer is coated with the photoresist. Then, through a mask, the photoresist is developed by UV-light. The mask passes UV-light only at positions, where the photoresist shall remain (i.e. where the desired conductor traces shall be provided). While developing the resist (and the polymer, respectively) is cross-linking at the positions which have been exposed to UV-light. After developing, the photoresist which was not exposed (and not developed, respectively) can be easily washed away. In the present case, a photoresist may not be applied to protect metal paths, but to form cavities in which the protrusion may be formed (e.g. plated).

According to a further embodiment, the method further comprises i) forming a photo-imageable dielectric, PID, layer structure on the high temperature resistant layer, in particular on the structured layer with the plurality of protrusions; ii) removing a part of the PID structure, thereby forming a base structure cavity; and iii) forming the base structure in the base structure cavity.

In the context of the present document, the term “photo-imageable dielectric layer structure” may refer to any dielectric (layer) structure that is configured to be treated (shows an effect) using photo-imaging. In particular, the term refers to a PID dielectric layer structure into which a cavity can be formed using (only) photo-imaging techniques. Preferably, a PID layer structure comprises a non-fiber enforced resin, e.g. polyimide. A base material for a PID application may include: i) thermosetting material, e.g. epoxy, BCB, phenol, ii) thermoplastic material: PI, PBO. The PID material may further comprise a photo initiator (photo sensitive agent) that may be cured by electromagnetic waves e.g. visible light and/or UV light. The PID material may be laminated on a substrate (e.g. the stack) and may then be exposed to a lithographic source via a pattern mask, wherein the pattern mask defines the to be manufactured cavities. Additionally and/or alternatively, the PID material may be applied by other techniques e.g. spraying, spin coating and/or slit coating. A portion of the PID material may be developed (exposed to electromagnetic waves) and one of an exposed portion and an unexposed portion (positive or negative photolithography may be used) may be removed to obtain a plurality of cavities. Examples of photolithography processes may include X-ray lithography, UV lithography, stereo lithography, e-beam lithography and laser lithography.

According to a further embodiment, the photo-imageable material comprises advanced adhesion properties (said adhesion properties may be created be the PID material and/or by adhesion promoting additives). This may provide the advantage that the layer structure may stick to the porous layer structures in an efficient and stable manner. Further, the metal layer structure may be reliably attached to such an adhesive layer structure. This may provide a particular advantage, because copper/resin interfaces tend to be unstable regarding adhesion, in particular if no additional surface roughing is provided. Further, the adhesion may promote a stable connection with component carrier material.

According to a further embodiment, the photo-imageable material comprises or consists of a polymer, in particular a mixture of polymers. This may provide the advantage that adhesion properties may be enhanced, particularly by hydrophobic interaction of polymer(s).

According to a further embodiment, the photo-imageable material comprises or consists of photo-imageable dielectric, PID, material the photo-imageable material comprises additives, in particular conjugated pi systems.

The term “conjugated pi system” may refer to a system of connected p-orbitals with delocalized electrons in a molecule, which in general lowers the overall energy of the molecule and increases stability. Examples of such systems may include aromatic (in particular heterocycles), non-aromatic, and anti-aromatic compounds. Specific examples may include nitrogen-compounds (in particular imidazole), phosphorus-compounds, oxygen compounds, or sulfur-compounds.

According to a further embodiment, the method further comprises forming the base structure subsequently to forming the plurality of protrusions on top of the plurality of protrusions, in particular by plating. Plating may be done directly on top of the plurality of protrusions. In this manner, the base structure and the protrusions may be connected.

According to a further embodiment, the semi-finished product (the high temperature resistant dielectric layer and the PID layer structure) comprises a height of 300 μm or less, in particular 250 μm or less.

In an embodiment, the stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die as an example of an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

FIG. 1 illustrates a component carrier according to an example embodiment of the disclosure.

FIG. 2A, FIG. 2B, FIG. 3A, and FIG. 3B illustrate further component carriers according to example embodiments of the disclosure.

FIG. 4A, FIG. 4B, and FIG. 4C illustrate a method of manufacturing a component carrier according to an example embodiment of the disclosure.

FIG. 5A, FIG. 5B, FIG. 5C, FIG. 5D, FIG. 5E, and FIG. 5F illustrate a method of manufacturing a component carrier according to an example embodiment of the disclosure.

FIG. 6 illustrates heat dissipation of the component carrier according to an example embodiment of the disclosure.

FIG. 7 and FIG. 8 illustrate the component carrier with additionally mounted components according to example embodiments of the disclosure.

### DETAILED DESCRIPTION OF THE ILLUSTRATED EMBODIMENTS

The illustrations in the drawings are schematically presented. In different drawings, similar or identical elements are provided with the same reference signs.

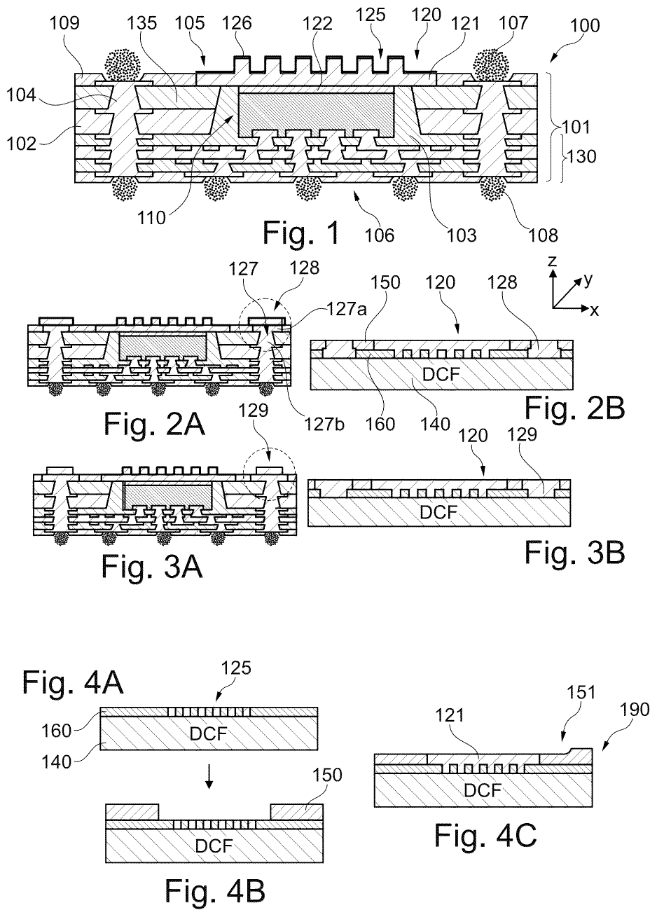

FIG. 1 illustrates a component carrier 100 according to an example embodiment of the disclosure. The component carrier 100 can be a coreless component carrier 100 and comprises a multilayer stack 101 with a plurality of electrically conductive layer structures (copper traces, vias) and electrically insulating layer structures 102 (in particular resin). An electronic component (active or passive) 110 is embedded in the stack 101. The electronic component 110 can be encapsulated by a specific encapsulation material 103 at the sidewalls and at the bottom.

On top of the electronic component 100, there is mounted a thermal structure 120, configured to dissipate thermal energy (heat) produced by the electronic component 110 towards and beyond a main surface 105 of the stack 101. In the present example, the main surface 105 is the upper main surface that is parallel to the directions of main extension (along the x- and y-axes) of the component carrier 100.

The thermal structure 120 comprises a base structure 121 that is mounted on the stack 101 (in particular on the electronic component 110) and is preferably additionally embedded in a solder resist layer structure 109 of the component carrier 100, so that the base structure 121 is flush with the solder resist layer structure 109. Thus, the base structure 121 can be the outermost layer (together with said solder resist layer structure 109) of the stack 101. It can be seen that the base structure 121 preferably comprises a larger width than the electronic component 110 and the cavity in which the component 110 is encapsulated 103.

Further, the thermal structure 120 comprises a plurality of protrusions 125, protruding from the base structure 121, and extending beyond the main surface 105 of the stack 101. The plurality of protrusions 125 is connected (for example monolithically connected, formed in one piece) to the base structure 121. A coating layer 126 preferably being a surface finish covers the plurality of protrusions 125.

In this example, the plurality of protrusions 125 are of the same shape, comprise a height in the range 100 μm to 200 μm, and comprise vertical sidewalls (reflecting a manufacture step of photolithography). Alternatively (at least some of) the plurality of protrusions 125 can have a different shape.

A thermal path T (see FIG. 6) is preferably established directly from the electronic component 110 to the thermal structure 120) without an electrically insulating layer structure 102 in between. The preferred adhesion layer 122 shown in the Figure is not considered as an electrically insulating layer structure 102 of the stack 101.

The component carrier 100 preferably comprises a redistribution layer structure 130, comprising a plurality of metal traces and vias, that is embedded in the stack 101 and arranged below the embedded electronic component 110. Small pads at the lower main surface of the electronic component 110 are electrically connected to the redistribution layer structure 130, whereby the redistribution layer structure 130 translates the small pad electric connections to large (lower) electric connections (in this example solder balls 108) at a further main surface 106 of the stack 101, which further main surface 106 is opposite to the main surface 105.

A vertical electric connection 127 (through via) is preferably embedded in the stack 101 and extends through the stack 101. An upper part of the vertical electric connection 127a is electrically connectable at the main surface 105 of the stack 101, in this example via a solder ball 107 (upper electric connection). Finally, a protection layer 135 can be embedded in the stack 101 and is arranged directly below the thermal structure 120 yet interrupted by the electric component 110 (the protection layer 135 is arranged around the electric component 110).

FIG. 2A and FIG. 2B illustrate a further component carrier 100 according to an example embodiment of the disclosure.

In FIG. 2A the component carrier 100 is very similar to the one described for FIG. 1 but comprises instead of the upper electric connection 107 a first metal structure 128 arranged besides the thermal structure 120 (here besides the plurality of protrusions 125). The metal structure 128 extends beyond the main surface 105 and forms the outermost portion of the vertical electric connection 127 arranged on top of the upper part of the vertical electric connection 127a. In this example, the metal structure 128 comprises a larger width than said upper part of the vertical electric connection 127a.

The component carrier 100 of FIG. 2B is shown as a semi-finished product during manufacturing. On a DCF substrate 140, there is formed the thermal structure 120 that will be later-on joined with the stack 101. A dry film resist 160 is applied between the plurality of protrusions 125, while the base structure 121 is embedded in a photo-imaginable dielectric 150. Together with the thermal structure 120, there are formed the metal structures 128 on both sides of the thermal structure 120. These will be transferred later-on together with the thermal structure 120 to the rest of the stack 101 and joined with the vertical electric connection 127. On the same level as the base structure 121, there is formed the upper part of the vertical electric connection 127a, while on the same level as the protrusions 125, there is formed the metal structure 128. As in FIG. 2A, the metal structure 128 comprises a larger width than said upper part of the vertical electric connection 127a.

FIG. 3A and FIG. 3B illustrate a further component carrier 100 according to an example embodiment of the disclosure. The component carrier 100 of FIG. 3A and the semi-finished product of FIG. 3B are very similar to those described for FIGS. 2A and 2B above. The difference being that in FIGS. 3A and 3B, the second metal structure 129 comprises a smaller width than said upper part of the vertical electric connection 127a.

FIG. 4A, FIG. 4B, and FIG. 4C illustrate a method of manufacturing a component carrier 100 according to an example embodiment of the disclosure. A part of this method has already been described for FIGS. 2B and 3B above.

FIG. 4A shows a high temperature resistant layer 160 such as a dry film (resist) is provided on a DCF substrate 140 as a temporary carrier. The high temperature resistant layer 160 is patterned (e.g. by a photolithographic method) to obtain recesses. The recesses are filled with metal to produce a preform of the plurality of protrusions 125.

FIG. 4B shows a photo-imageable dielectric, PID, layer structure 150 is arranged on top of the high temperature resistant layer 160 and the protrusion 125 preforms. An opening (base structure cavity) is formed in the PID layer 160 above the protrusion 125 preforms.

FIG. 4C shows a semi-finished product 190 wherein the opening in the PID layer 160 has been filled with metal (copper) to thereby form the base structure 121 directly on top of the plurality of protrusions 125. A grinding step 151 is preferably performed, so that the PID layer 160 and the base structure 121 are made flush.

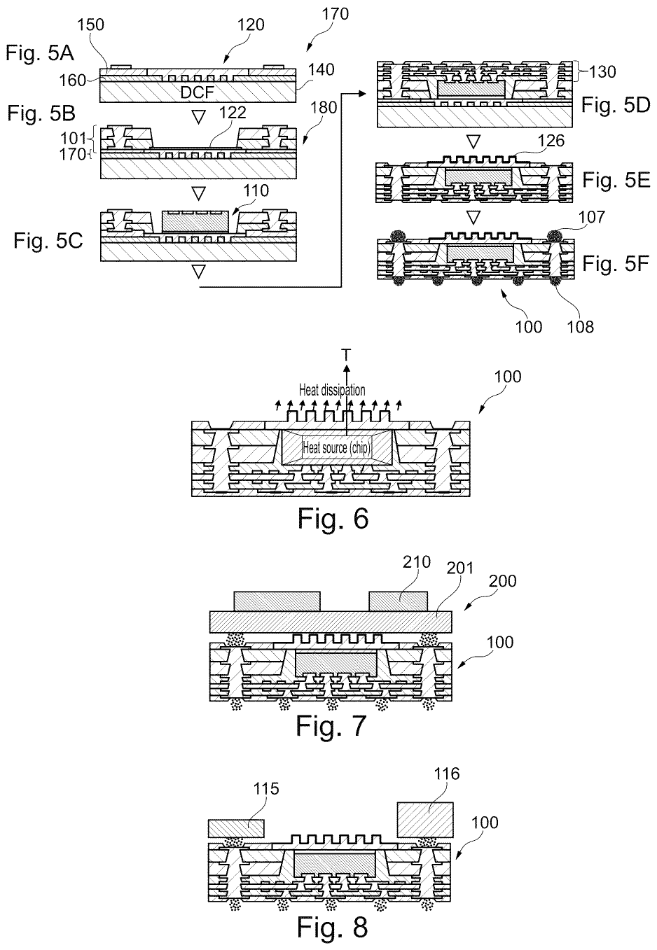

FIG. 5A, FIG. 5B, FIG. 5C, FIG. 5D, FIG. 5E, and FIG. 5F illustrate a method of manufacturing a component carrier 100 according to an example embodiment of the disclosure.

In FIG. 5A, the semi-finished product of FIG. 4C is provided and metal traces are formed on the PID layer 160.

In FIG. 5B, the base structure 121 is covered by an adhesion layer 122 and build-up of the stack 101 is performed. In the first place, the protection layer 135 is formed and on top an electrically insulating layer structure 102. Through said layers, the vertical electric connection 127 is formed and electrically connected to the metal traces formed in FIG. 5A. Then, a cavity is formed in the stack 101 for embedded the electronic component 110.

In FIG. 5C, the electronic component 110, with electric connection pads on top, is placed in the cavity and on the adhesion layer 122.

In FIG. 5D, a further layer build-up is performed, whereby the redistribution structure 130 is obtained.

In FIG. 5E, the component carrier under production is flipped and the DCF substrate 140 is removed. The dry film resist 160 is removed as well, so that the plurality of protrusions 125 is now exposed and protrudes from the component carrier main surface 105. A coating 126 (surface finish) is preferably provided to the protrusions 125. The PID layer 150 is not removed and forms in this example the solder resist layer structure 109 that surrounds the base structure 121. Thus, base structure 121 and PID layer 150/solder resist layer structure 109 are flush (have the same height).

In FIG. 5F, upper and lower electric connections 107, 108 in form of solder balls are provided.

FIG. 6 illustrates heat dissipation of the component carrier 100 according to an example embodiment of the disclosure. The component carrier 100 is essentially the same as described for FIG. 1. The electronic component 110 is an integrated circuit (chip) that produces a high amount of heat. Said heat is directly guided through the base structure 121 and the plurality of protrusions 125 beyond the main surface 105 of the component carrier 100. This heat dissipation path can be termed thermal path T.

FIG. 7 and FIG. 8 illustrate the component carrier 100 of FIG. 1 with additionally mounted components according to example embodiments of the disclosure.

FIG. 7 includes a component carrier arrangement 200 formed by stacking a further component carrier 201 on the main surface 105 of the component carrier 100. The further component carrier 201 comprises two surface-mounted further electronic components 210 that face away from the thermal structure 120. The further component carrier 201 does not directly contact the component carrier 100, because there is a spacer structure in between, in this example the solder balls 107 are applied for this purpose. In this manner, the thermal structure 120 is not hindered in dissipating heat beyond the component carrier main surface 105.

FIG. 8 illustrates a further electronic component 115 and another electronic component 116 arranged on top of the component carrier 100. In this example, a direct electric connection is established via upper electric connections 107 of the main surface 105.

### REFERENCE SIGNS

100 Component carrier
101 Stack
102 Electrically insulating layer structure
103 Encapsulation material
104 Electrically conductive layer structure
105 Main surface
106 Further main surface
107 Upper electric connection
108 Lower electric connection
109 Surface finish
110 Electronic component
115 Further electronic component
116 Other electronic component
120 Thermal structure
121 Base structure
122 Adhesive layer
125 Protrusion
126 Thermal structure surface finish
127 Vertical electric connection, through via
127a Upper part of via
127b Lower part of via
128 First metal structure
129 Second metal structure
130 Redistribution layer structure
135 Protection layer
140 Temporary carrier
150 PID layer structure
151 Grinding
160 High temperature material, dry film resist
170 Semi-finished thermal structure
180 Semi-finished stack
190 Semi-finished product
200 Arrangement
201 Further component carrier
210 Further component
T Thermal path

1. A component carrier, comprising:
a stack comprising at least one electrically conductive layer structure and/or at least one electrically insulating layer structure,
an electronic component embedded in the stack; and
a thermal structure, configured to dissipate thermal energy produced by the electronic component towards and beyond a main surface of the stack, wherein the thermal structure includes
a base structure mounted on and/or at least partially embedded in the stack, and
a plurality of protrusions, protruding from the base structure, and extending beyond the main surface of the stack.

2. The component carrier according to claim 1, further comprising:
a redistribution layer structure, at least partially embedded in the stack and configured to electrically connect the embedded electronic component to a further main surface of the stack,
wherein the further main surface is opposed to the main surface.

3. The component carrier according to claim 1, comprising at least one of the following features:
wherein the component carrier is configured as a coreless component carrier;
wherein the component carrier is configured as a fan-out wafer-level-package or a fan-out panel level package;
wherein the component carrier is configured as a high density package for heat production;
wherein the thermal structure is configured as an integral part of the stack;
wherein the base structure is the outermost layer of the stack.

4. The component carrier according to claim 1,
wherein the thermal structure further comprises:
a coating layer that covers the plurality of protrusions.

5. The component carrier according to claim 1, comprising at least one of the following features:
wherein the plurality of protrusions comprise a height in the range 100 μm to 200 μm;
wherein the plurality of protrusions comprise essentially vertical sidewalls reflecting a manufacture step of photolithography;
wherein the protrusions of the plurality of protrusions comprise the same shape;
wherein the base structure comprises a larger width than the electronic component;
wherein the electronic component is embedded in a cavity and wherein the base structure comprises a larger width than the cavity;
wherein a thermal path is established directly from the electronic component to the thermal structure without an electrically insulating material in between.

6. The component carrier according to claim 1, further comprising:
a vertical electric connection embedded in the stack, wherein the vertical electric connection extends through the stack, wherein an upper part of the vertical electric connection is electrically connectable at the main surface of the stack.

7. The component carrier according to claim 6, further comprising:
a metal structure arranged besides the thermal structure, wherein the metal structure extends at least partially beyond the main surface,
wherein the metal structure forms the outermost portion of the vertical electric connection,
wherein the metal structure comprises a larger width than the upper part of the vertical electric connection.

8. The component carrier according to claim 7,
wherein the metal structure comprises the same height as the plurality of protrusions; and/or
wherein the upper part of the vertical electric connection is arranged at the same vertical height as the base structure.

9. The component carrier according to claim 1, further comprising:
an adhesive layer, embedded in the stack and arranged below the thermal structure.

10. An arrangement, comprising:
a component carrier according to claim 1; and
a further component carrier, stacked on the main surface of the component carrier,
wherein the further component carrier comprises at least one further electronic component.

11. A method for manufacturing a component carrier, the method comprising:
forming a stack comprising at least one electrically conductive layer structure and/or at least one electrically insulating layer structure,
embedding an electronic component in the stack; and
forming a thermal structure, so that the thermal structure dissipates thermal energy produced by the electronic component towards a main surface of the stack,
wherein the thermal layer structure comprises a base structure mounted on and/or at least partially embedded in the stack, and a plurality of protrusions, protruding from the base structure, and extending beyond the main surface of the stack.

12. The method according to claim 11, further comprising:
forming the thermal structure on a temporary carrier.

13. The method according to claim 11, further comprising:
providing a high temperature resistant dielectric layer;
patterning the high temperature resistant layer to obtain a structured layer with recesses; and
forming the plurality of protrusions in the recesses of the structured layer by plating.

14. The method according to claim 13, further comprising:
forming a photo-imageable dielectric (PID) layer structure on the high temperature resistant layer;
removing a part of the PID structure, thereby forming a base structure cavity; and
forming the base structure in the base structure cavity by plating.

15. The method according to claim 11, further comprising:
forming the base structure subsequently to forming the plurality of protrusions on top of the plurality of protrusions by plating.

16. A semi-finished product, comprising:
a high temperature resistant layer; and
a photo-imageable dielectric (PID) layer structure on top of the high temperature resistant layer.
